(19) United States
(12) Patent Application Publication
(10) Pub. No.: US 2019/0272787 A1
(43) Pub. Date: Sep. 5, 2019

(54) DISPLAY PANELS AND TERMINALS

(71) Applicant: Yungu (Gu'an) Technology Co., Ltd., Langfang (CN)

(72) Inventors: Xiaokang ZHOU, Kunshan (CN); Mengzhen LI, Kunshan (CN); Hui PANG, Kunshan (CN); Yangjie ZHU, Kunshan (CN)

(73) Assignee: Yungu (Gu'an) Technology Co., Ltd., Langfang (CN)

(21) Appl. No.: 16/416,777

(22) Filed: May 20, 2019

Related U.S. Application Data
(63) Continuation of application No. PCT/CN2018/092006, filed on Jun. 20, 2018.

(30) Foreign Application Priority Data
Oct. 31, 2017 (CN) 201711049055.1

(51) Int. Cl. G09G 3/3225

(52) U.S. Cl. CPC G09G 3/3225; G09G 2300/0426; G09G 2330/02; G09G 2320/0233

(57) ABSTRACT

A display panel and a terminal are provided. The display panel includes a plurality of light emitting modules arranged side by side in a plurality of columns; and a cathode module and an anode module for supplying power to the plurality of the light emitting modules. The cathode module has a plurality of cathode strips arranged spaced-apart, each of the cathode strips covering and being electrically connected to the light emitting module in a same column. The anode module has a plurality of anode power supply lines, each of the anode power supply lines being electrically connected to the light emitting modules in a same column.

### CROSS-REFERENCE TO RELATED APPLICATIONS

This application is a continuation of International application No. PCT/CN2018/092006, filed on Jun. 20, 2018, which is based upon and claims priority to Chinese Patent Application No. 201711049055.1, filed on Oct. 31, 2017, with a title “DISPLAY PANELS AND TERMINALS”, the entire contents of which are hereby incorporated by reference.

### FIELD

The application relates to display technologies, and more particularly to display panels and terminals.

### BACKGROUND

An Organic Light Emitting Diode (OLED) display panel includes a plurality of sub-pixel regions defined by a plurality of scanning lines SSL, a plurality of data lines DataL, and a plurality of anode power supply lines DDL, and a whole cathode is arranged in the display panel to cover all of the sub-pixel regions. Cathode power supply lines are arranged around the cathode, and a top side of the cathode in a longitudinal direction and two sides of the cathode in a transverse direction are connected to the cathode power supply lines.

Due to a resistor divider of the anode supply lines DDL, resistance voltage drop phenomenon occurs to the anode supply line DDL, that is, a certain voltage drop occurs when a current passes through the anode supply lines DDL. Therefore, the sub-pixel regions located at different positions are affected by the resistance voltage drop to different extents. For example, a power supply voltage received by sub-pixel regions at a near end of the display panel (close to a power supply circuit or a power supply lead line) is greater than a power supply voltage received by sub-pixel regions at a far end (far from the power supply circuit) of the display panel, resulting in an uneven brightness of the display panel.

### SUMMARY

To solve the above technical problem, exemplary embodiments of the application provides a display panel, including:

a plurality of light emitting modules arranged side by side in a plurality of columns, a cathode module and an anode module for supplying power to a plurality of the light emitting modules, the cathode module including a plurality of spaced-apart cathode strips, each of the cathode strips covering and being electrically connected to the light emitting module in a same column, the anode module including a plurality of anode power supply lines, each of the anode power supply lines being electrically connected to the light emitting modules in a same column, and a portion of the cathode strip corresponding to the light emitting module forming a cathode unit which generates a resistance equal to a resistance generated by the anode power supply line located in the light emitting module.

Further, the display panel further includes a cathode power supply lines arranged at a periphery of the cathode module, an extension direction of the anode power supply line is defined as a longitudinal direction, and a direction perpendicular to the longitudinal direction is defined as a lateral direction, the cathode module extends in the longitudinal direction and one end thereof is connected to the cathode power supply line, and the lateral two sides of the cathode module are insulated from the cathode power supply line.

Further, a plurality of the cathode strips are spaced apart by an equal distance.

Further, the display panel includes a plurality of sub-pixel regions, the cathode strip includes a plurality of consecutive cathode units, and each of the sub-pixel regions includes one of the light emitting modules and the cathode unit.

Further, the cathode is a regular stripe.

Further, a width of the cathode unit in a longitudinal extension direction is varied.

Further, the cathode unit has two different widths in a longitudinal extension direction.

Further, the cathode unit includes a first cathode block and a second cathode block connected to the first cathode block, and the first cathode block has a width greater than that of the second cathode block.

Further, the cathode strip is plated with Indium Tin Oxide.

Further, a material of the cathode strip is a MgAg alloy.

To overcome the above technical problem, the terminal is provided by the application, including the display panel mentioned above.

Compared with the prior art, in the display panel of the application, a cathode module arranged therein are a plurality of spaced-apart cathode strips, and each cathode strip and each anode power supply line are electrically connected to a group of light emitting modules in the same column, respectively, thus each of the light emitting modules has a same voltage difference in the extension direction of the anode power supply line, so that the display panel has an uniform brightness, which solves the problem of uneven display caused by a resistance voltage drop of the anode power supply line.

### BRIEF DESCRIPTION OF THE DRAWINGS

FIG. 1 is a schematic view of a display panel in an exemplary embodiment of the application;

FIG. 2 is a schematic view of a unit circuit in a display panel according to an exemplary embodiment of the application;

FIG. 3 is a schematic view of a cathode module in a display panel according to an exemplary embodiment of the application;

FIG. 4 is a schematic view of a light emitting module in a display panel according to an exemplary embodiment of the application;

FIG. 5 is a schematic diagram of a driving circuit in a display panel according to an exemplary embodiment of the application;

FIG. 6 is a schematic view of another cathode module in a display panel according to an exemplary embodiment of the application.

### DETAILED DESCRIPTION

In order to make objects, technical solutions and advantages of the application clear, technical solutions of the application will be clearly and completely described in the following with reference to specific exemplary embodiments of the application and corresponding drawings. It is apparent that the described embodiments are only a part of the embodiments of the application rather than all of them. All other embodiments obtained by a person skilled in the art based on the embodiments of the application without creative efforts fall into the protection scope of the application.

Directional terms mentioned in the application, such as “horizontal”, “longitudinal”, etc., are merely directions to which additional drawings are referred. Therefore, the directional terms is used for the purpose of illustrating and understanding, and is not intended to limit the application. Dimensions of each of the components shown in the drawings are arbitrarily shown for the sake of understanding and convenience of description, but the application is not limited thereto.

In addition, in the specification, unless explicitly described as the opposite, the word “comprising” is to be understood to include said components, but does not exclude any other components.

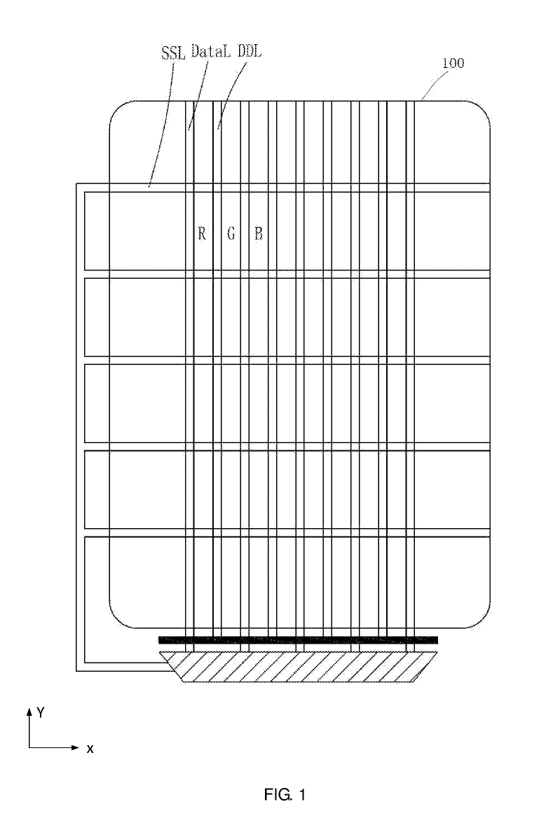

As shown in FIG. 1, the application provides a display panel 100 including a substrate (not shown).

A material of the substrate may be a glass, a quartz, an organic polymer, or an opaque/reflective material (for example, conductive material, wafer, ceramic, or other applicable materials), or other applicable materials.

The display panel 100 further includes a plurality of scanning lines SSL, a plurality of data lines DataL, a plurality of anode power supply lines DDL, and a plurality of unit circuit structures located above the substrate. The plurality of scanning lines SSL intersect with the plurality of data lines DataL and the plurality of anode power supply lines DDL to define sub-pixel regions of various colors. And each of the sub-pixel regions is provided with a unit circuit structure. In this embodiment, a plurality of scanning lines SSL intersect with a plurality of data lines DataL and a plurality of anode power supply lines DDL to define sub-pixel regions in three colors, a red sub-pixel region R, a green sub-pixel region G, and a blue sub-pixel region B respectively. Of course, in other exemplary embodiments, a color type, a quantity and an arrangement manner of sub-pixel regions may be different from that of the present embodiment, and the application is not limited thereto. The unit circuit includes a switching transistor, a driving transistor, a storage capacitor, and a unit light emitting device.

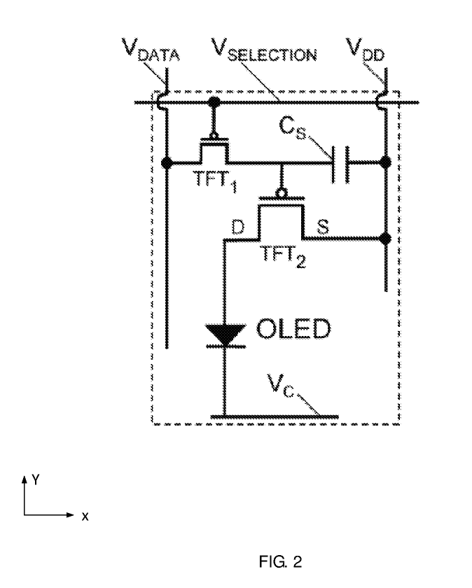

As shown in FIG. 2, the following unit circuit structure takes 2T1C structure as an example, and an electrical relationship between the scanning line SSL, the data line DataL, the anode power supply line DDL, and the unit circuit structure will be specifically described, but the unit circuit structure of the display panel 100 of the application is not limited thereto, and may be other structures such as 8T1C, 9T1C, and the like.

Each of scanning lines SSL extends in a lateral direction (a X direction shown in FIG. 2), and a plurality of scanning lines SSL are arranged spaced apart in a longitudinal direction (a Y direction shown in FIG. 2). In the present embodiment, a metal material is selected for the scanning line SSL, but the application is not limited thereto. The material of the scanning line SSL may also be selected as conductive materials, such as an alloy, a nitride of a metal material, an oxide of a metal material, and a nitrogen oxide of a metal material or the like. A scanning line on one side of each sub-pixel region is electrically connected to a gate of a switching transistor in the sub-pixel region to provide a gate voltage Vselection for the switching transistor.

Each of data lines DataL extends in the longitudinal direction, and a plurality of data lines DataL are arranged spaced apart in the lateral direction. In the present embodiment, a metal material is selected for the data line DataL, but the application is not limited thereto. Conductive materials may also be selected for the material of the data line DataL, such as an alloy, a nitride of a metal material, an oxide of a metal material, and a nitrogen oxide of a metal material or the like. A data line DataL on one side of each sub-pixel region is electrically connected to a source of the switching transistor in the sub-pixel region, and provides a data signal Vdata to the switching transistor.

Each of anode power supply lines DDL extends in the longitudinal direction, and a plurality of anode power supply lines DDL are arranged spaced apart in the lateral direction. In this embodiment, a metal material is selected for the anode power supply line DDL, but the application is not limited thereto. Conductive materials may also be selected for the material of the anode power supply line DDL, such as an alloy, a nitride of a metal material, an oxide of a metal material, and a nitrogen oxide of a metal material or the like. In one exemplary embodiment, a plurality of anode supply lines DDL and a plurality of data lines DataL are formed in a same layer. And there is an insulating layer (not shown) between the plurality of anode supply lines DDL and the plurality of scanning lines SSL. A anode power supply line DDL on one side of each sub-pixel region is electrically connected to a source of the driving transistor in the sub-pixel region, and supplies a driving power supply voltage Vdd to the driving transistor.

The unit circuit structure includes a switching transistor TFT1, a driving transistor TFT2, a storage capacitor Cs, and a unit light emitting device OLED. A gate, a source, and a drain of the switching transistor TFT1 are electrically connected to the scanning line SSL, the data line DataL, and a gate of the driving transistor TFT2, respectively. A source and a drain of the driving transistor TFT2 are electrically connected to the anode power supply line DDL and the unit light emitting device OLED, respectively. One end of the storage capacitor Cs is electrically connected to a gate of the driving transistor TFT2, and the other end of the storage capacitor Cs is electrically connected to the source of the driving transistor TFT2. Of course, the application is not limited thereto. In other exemplary embodiments, the other end of the storage capacitor Cs may be electrically connected to the drain of the driving transistor TFT2.

When the unit circuit structure operates, the gate of the switching transistor TFT1 is turned on by the scanning signal, and the data signal Vdata is introduced into the source of the switching transistor TFT1, thereby charging the storage capacitor Cs through the drain of the switching transistor TFT1. The storage capacitor Cs maintains a stabilization of the gate voltage of the driving transistor TFT2 for one frame. The driving transistor TFT2 generally operates in a saturation region, and supplies a driving current for the unit emitting device OLED by the drain of the driving transistor TFT2.

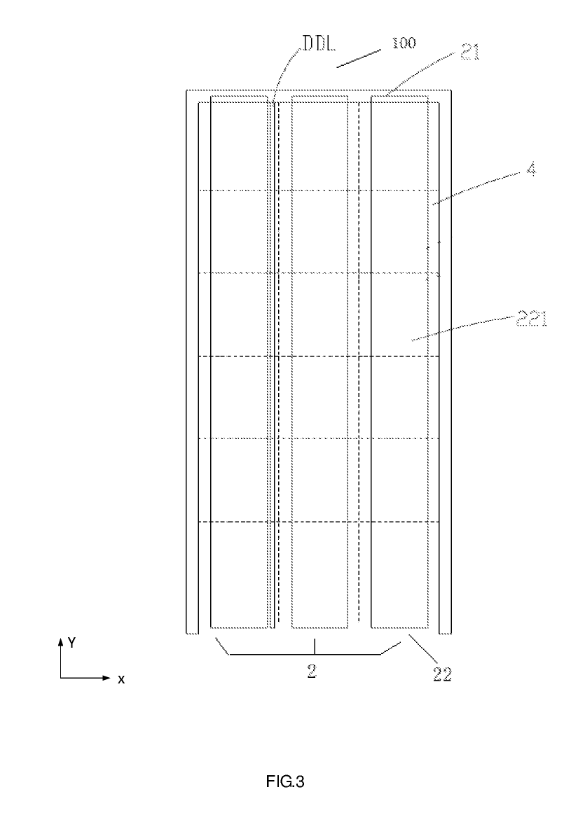

As shown in FIG. 3, the display panel 100 includes a cathode module 2 that is supplied with a voltage by cathode power supply lines 21 which is arranged at periphery of the cathode module 2 and around the cathode module 2. The cathode module 2 is patterned. Specifically, the cathode module 2 includes a plurality of spaced-apart cathode strips 22 extending in a same direction as the anode power supply line DDL. That is, in the present embodiment, the cathode strips 22 extend in a longitudinal direction (a Y direction shown in FIG. 3), and an upper end of the cathode module 2 is connected to the cathode power supply lines 21, and two sides of the cathode module 2 in a lateral direction (a X direction shown in FIG. 3) are insulated from the cathode power supply lines 21.

In the present embodiment, the cathode strips 22 are strip-shaped. And a plurality of strip-shaped cathode strips 22 are equally spaced apart. The cathode strip 22 includes a plurality of consecutive cathode units 221, and each of the cathode units 221 corresponds to a sub-pixel region 4.

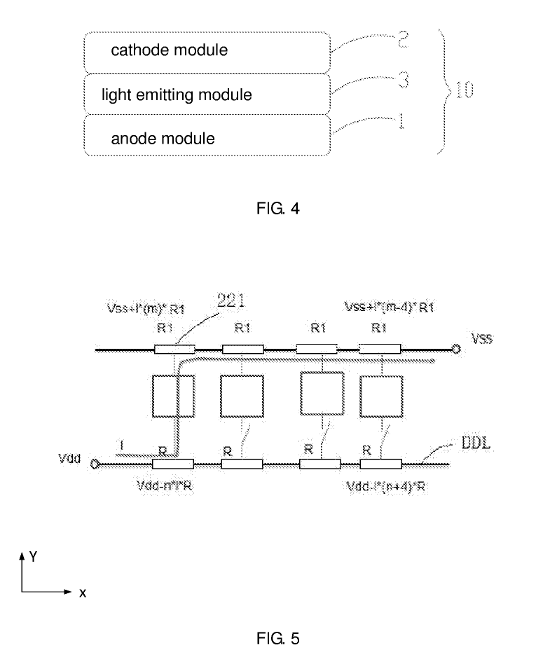

As shown in FIG. 3 and FIG. 4, a light emitting device 10 includes a anode module 1, a cathode module 2, and a plurality of light emitting modules 3 formed between the anode module 1 and the cathode module 2, both of modules being stacked. The anode module 1 includes a plurality of anode power supply lines DDL and a plurality of anode plates arranged in an array. The cathode module 2 and the anode module 1 respectively supply power to the light emitting module 3, and each cathode strip 22 covers and is electrically connected to a group of light emitting modules 3 in a same row of the plurality of light emitting modules 3. And each of the anode power supply lines DDL is electrically connected to a group of light emitting modules 3 in a same column in the plurality of light emitting modules 3. Each of the sub-pixel regions 4 includes a unit light emitting device composed of an anode plate, a cathode unit 2, and a light emitting module 3. The anode plate 1 is electrically connected to the drain of the driving transistor TFT2.

As shown in FIG. 5, both the cathode strip 22 and the anode supply line DDL extend in the longitudinal direction (i.e., the Y direction), whereby the direction of the current is from bottom to top in the longitudinal direction, and the voltage drop direction of the anode supply line DDL is also from bottom to top in the longitudinal direction. When the cathode module 2 is patterned, the voltage of each cathode strip 22 gradually decreases from bottom to top in the longitudinal extension direction, and the voltage of the cathode strip 22 decreases in the same direction as the voltage drop of the anode power supply lines DDL, and in a certain sub-pixel region, correspondingly:

The voltage of the cathode unit 221 is: V1=Vss+mIR1,

The voltage of this segment of anode power supply lines DDL is: V2=Vdd−nIR,

Vss is a supply voltage of the cathode power supply lines 21, Vdd is a voltage of an input end of the anode power supply lines DDL, and m is a number of pixel regions through which the sub-pixel region pass from top to bottom in a longitudinal direction of a sub-pixel structure, n is a number of pixel regions through which the sub-pixel region pass from bottom to top in the longitudinal direction of the sub-pixel structure, R1 is a resistance generated by the cathode unit 221, R is a resistance generated by a segment of the power supply line in single sub-pixel region, I is a driving current, and n+m is a constant value.

In the certain sub-pixel region, the voltage difference between the voltage of the cathode unit 221 and the voltage of the segment of the anode power supply lines DDL is:

ΔV=V2−V1=Vdd−Vss−nIR−mIR1,

In the present embodiment, a pixel size is 100 μm×100 μm, and sizes of the red sub-pixel region R, the green sub-pixel region G, and the blue sub-pixel region B are all 33 μm×100 μm. A square resistance of the anode supply line DDL is 0.2 Ω/square and a width of the anode supply line DDL is 2 μm. A square resistance of the cathode module 2 is 3 Ω/square, a plurality of cathode strips 22 are evenly distributed along the lateral direction. The cathode strips 22 are regular strips and have a width of 30 μm. The cathode strips 22 cover all of light emitting regions of the sub-pixel regions 4. In each of the sub-pixel regions 4, the resistance R generated by the segment of the anode supply lines DDR is R=0.2×100/2=10 ΩL, and the resistance R1 generated by the cathode unit 221 is R1=3×100/30=10Ω, that is, R1=R. That is, the resistance R1 generated by the cathode unit 221 is equal to the resistance R generated by the anode power supply lines DDL in the single sub-pixel region, so that in any one of the sub-pixel regions, the voltage difference between the voltage of the cathode unit 221 and the voltage of the anode power supply line DDL is ΔV=Vdd−Vss−(n+m) IR. Since n+m is a constant value, the voltage difference between the voltage of the cathode unit 221 and the voltage of the anode power supply lines DDL is the same in any one of the sub-pixel regions. Since a voltage difference between upper and lower sides of the light emitting module 3 in adjacent sub-pixel regions is the same, a luminance of each sub-pixel region can be the same, so that the display panel has an uniform brightness, and a display uniformity can be achieved.

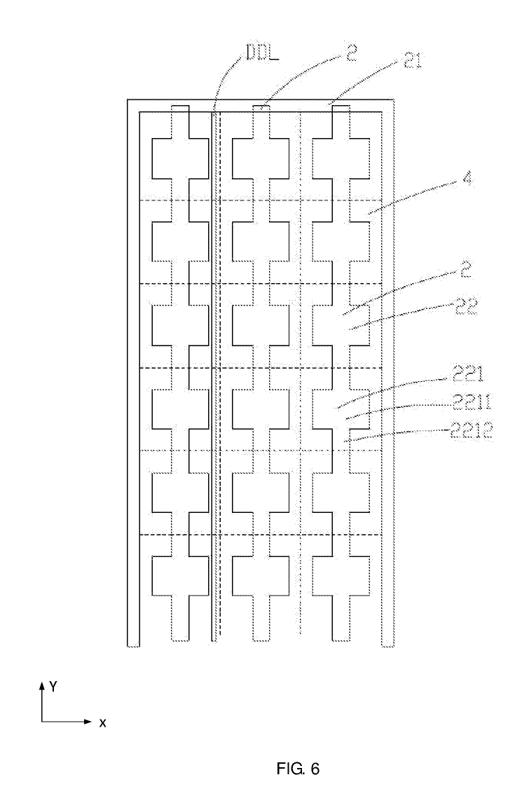

In other alternative embodiments, a shape of the cathode unit 221 may be varied within a single sub-pixel region, such that the resistance R1 of the cathode unit 221 and the resistance R of the anode supply lines DDL can be conveniently equalized. For example, the width of the cathode strip 22 in the longitudinal extension direction may be varied, but structures of the cathode units 221 in each sub-pixel region 4 are the same. In an exemplary embodiment, as shown in FIG. 6, the cathode unit 221 has a strip shape and two different widths in the longitudinal direction, and specifically, the cathode unit 221 including a first cathode block 2211 with a first width and a second cathode block 2212 with a second width, the second cathode block 2212 being connected to the cathode block 2211. The second width is greater than the first width. In this way, the cathode block 2211 can conveniently covers the light emitting module 3, which reduces a process difficulty.

In one exemplary embodiment, the cathode strip 22 is a MgAg alloy electrode and is patterned, a layer of Indium Tin Oxide (ITO) is formed on the electrode. And an ITO and MgAg alloy electrode are connected in parallel. Thus, by adjusting the shape of the cathode unit 221 and the thickness of the ITO in the sub-pixel region, the resistance R1 generated by the cathode unit 221 is equal to the resistance R generated by the power supply line in the single sub-pixel region, and the upper and lower sides of the light emitting module in the adjacent sub-pixel region can also have the same voltage difference, so that the display panel has uniform brightness, which solves the problem of uneven display caused by the resistance voltage drop of the anode power supply line DDL, thereby changing the resistance of the cathode strip 22 by more methods to more easily equalize the resistor R1 and the resistor R. In other alternative exemplary embodiments, the material of the cathode strip 22 is not limited to the MgAg electrode, and the plating outside the cathode strip 22 is not limited to ITO as long as the material of the plating layer is a transparent conductive material.

It is noted that, in exemplary embodiments of the present application, the light emitting module may be a light emitting component, the cathode module may be a cathode component, the anode module may be a anode component and the cathode unit may be a cathode element.

The exemplary embodiment of the application further provides a terminal, which includes a casing, a main board housed in the casing and the display panel mentioned above. In an exemplary embodiment, the terminal is applicable to a mobile phone.

The above description is only preferred embodiments of the application, and is not intended to limit the application in any form. Many possible variations and modifications to the technical solutions of the application by the method disclosed above by any person skilled in the art are intended to fall within the protection scope of the appended claims without departing from the scope of the technical solutions of the application.

What is claimed is:

1. A display panel, comprising:
a plurality of light emitting modules arranged side by side in a plurality of columns; and
a cathode module and an anode module for supplying power to the plurality of the light emitting modules, the cathode module comprising a plurality of cathode strips arranged spaced-apart, each of the cathode strips covering and being electrically connected to the light emitting module in a same column, the anode module comprising a plurality of anode power supply lines, each of the anode power supply lines being electrically connected to the light emitting modules in a same column, a portion of the cathode strip corresponding to the light emitting module forming a cathode unit, a resistance generated by a cathode unit being equal to a resistance generated by the anode power supply line located in the light emitting module.

2. The display panel according to claim 1, further comprising a cathode power supply line arranged at a periphery of the cathode module, an extension direction of the anode power supply lines being defined as a longitudinal direction, a direction perpendicular to the longitudinal direction being defined as a lateral direction, the cathode module extending in the longitudinal direction, one end of the cathode module being connected to the cathode power supply line, two sides of the cathode module in the lateral direction being insulated from the cathode power supply line.

3. The display panel according to claim 1, wherein the plurality of the cathode strips are spaced apart by an equal distance.

4. The display panel according to claim 2, comprising a plurality of sub-pixel regions, each of the cathode strips comprising a plurality of consecutive cathode units, each of the sub-pixel regions comprising one of the light emitting modules and one of the cathode units.

5. The display panel according to claim 4, wherein a width of each cathode unit in the longitudinal direction is varied.

6. The display panel according to claim 5, wherein each cathode unit has two different widths in the longitudinal direction.

7. The display panel according to claim 6, wherein the cathode unit comprises a first cathode block and a second cathode block connected to the first cathode block, and the first cathode block has a width greater than that of the second cathode block.

8. The display panel according to claim 1, wherein the cathode strips are plated with Indium Tin Oxide.

9. The display panel according to claim 8, wherein a material of the cathode strip is a MgAg alloy.

10. A terminal, comprising a display panel comprising:
a plurality of light emitting modules arranged side by side in a plurality of columns; and
a cathode module and an anode module for supplying power to the plurality of the light emitting modules, the cathode module comprising a plurality of cathode strips arranged spaced-apart, each of the cathode strips covering and being electrically connected to the light emitting module in a same column, the anode module comprising a plurality of anode power supply lines, each of the anode power supply lines being electrically connected to the light emitting modules in a same column, a portion of the cathode strip corresponding to the light emitting module forming a cathode unit, a resistance generated by a cathode unit being equal to a resistance generated by the anode power supply line located in the light emitting module.
